(19) United States
(12) Patent Application Publication
(10) Pub. No.: US 2019/0265939 A1
(43) Pub. Date: Aug. 29, 2019

(54) Modular Display Configuration

(71) Applicant: Ultravision Technologies, LLC, Dallas, TX (US)

(72) Inventor: Matthew Foster, Flower Mound, TX (US)

(21) Appl. No.: 15/904,137

(22) Filed: Feb. 23, 2018

(51) Int. Cl. G06F 3/14; G09G 3/32; H05K 5/02; G09F 9/302

(52) U.S. Cl. CPC G06F 3/1446; G09G 3/32; G09G 2340/0464; G09F 9/3023; H05K 5/0256

(57) ABSTRACT

A method for configuring a modular display system includes attaching a panel to form the modular display system having a display area and initiating, by the panel in the modular display system, a configuration of the panel in response to the attaching. In this embodiment, the configuration of the panel includes panel orientation, panel resolution, panel vertical and horizontal pixel information, or panel spatial configuration in the modular display system. The method also includes displaying, by the panel, a corresponding segment of an image, video, or text, where the corresponding segment is in accordance with the configuration of the panel.

### TECHNICAL FIELD

The present invention relates generally to a display, and, in particular embodiments, to a system and method for a scalable and a self-configurable display panel in large displays.

### BACKGROUND

Large displays (e.g., billboards), such as those commonly used for advertising in cities and along roads, are widely used to display an image, a video, or a text. The graphics may be projected on a single panel or extended across multiple panels. Each panel may have an array of light emitting diodes (LEDs) to generate the visual graphics. The LED panels may be conventional panels made using discrete LEDs or surface-mounted device (SMD) panels. Most outdoor screens and some indoor screens are built around discrete LEDs, which are also known as individually mounted LEDs. A cluster of red, green, and blue diodes, or alternatively, a tri-color diode, is driven together to form a full-color pixel, usually square in shape. These pixels are spaced evenly apart and are measured from center to center for absolute pixel resolution.

In a typical large display with multiple panels, each panel displays a segment or a portion of an image, which when combined form the complete image. Generally, in an installation, human intervention is required to configure each panel to properly display the corresponding segment in accordance with the panel's spatial configuration. Likewise, during a panel replacement or a panel upgrade, the individual panel, and in some cases the entire display, may need to be reconfigured to properly display the corresponding segment. These manual configurations increase installation time, cost, and labor. A less manual process is advantageous.

### SUMMARY

Technical advantages are generally achieved by embodiments of this disclosure, which describe systems and methods for a scalable and a self-configurable display panel in large displays.

In accordance with an embodiment, a method for configuring a modular display includes attaching a panel to form the modular display system having a display area. The method further includes initiating, by the panel in the modular display system, a configuration of the panel in response to the attaching. In this embodiment, the configuration of the panel includes panel orientation, panel resolution, panel vertical and horizontal pixel information, or panel spatial configuration in the modular display system. The method also includes displaying, by the panel, a corresponding segment of an image, video, or text, where the corresponding segment is in accordance with the configuration of the panel.

In accordance with another embodiment, a panel in a modular display system is provided. The panel includes a substrate assembly and a receiver circuit. In this embodiment, the substrate assembly includes a printed circuit board (PCB) having a first side and a second side, a plurality of LEDs coupled to the first side of the PCB, and a driver circuit coupled to the second side of the PCB. The driver circuit is configured to drive the plurality of LEDs. The receiver circuit is connected to the substrate assembly and includes a non-transitory memory storage comprising instructions and a processor in communication with the non-transitory memory storage. The processor executes instructions to initiate a configuration of the panel in response to attaching the panel in a modular display system, the configuration of the panel including panel orientation, panel resolution, panel vertical and horizontal pixel information, or panel spatial configuration in the modular display system. The processor also executes instructions to transmit a corresponding segment of an image, video, or text to be displayed using the substrate assembly. The corresponding segment being in accordance with the configuration of the panel.

In accordance with yet another embodiment, a modular display system is provided. The modular system includes a plurality of panels and a data receiver box. Each panel includes a printed circuit board (PCB) having a first side and a second side, a plurality of LEDs coupled to the first side of the PCB, and a driver circuit coupled to the second side of the PCB. The driver circuit configured to drive the plurality of LEDs. The data receiver box is configured to connect a first panel to a second panel of the plurality of panels and includes a receiver circuit and a power supply circuit. The receiver circuit is configured to initiate a configuration of the first panel and a configuration of the second panel in response to attaching the first panel or the second panel in the modular display system. The configuration of the first panel and the configuration of the second panel includes panel orientation, panel resolution, panel vertical and horizontal pixel information, or panel spatial configuration in the modular display system. The receiver circuit is also configured to transmit a first segment of an image, video, or text to the first panel to be displayed. The first segment being in accordance with the configuration of the first panel. The receiver circuit is further configured to transmit a second segment of an image, video, or text to the second panel to be displayed. The second segment being in accordance with the configuration of the second panel. The power supply circuit is configured to convert an alternating current (AC) signal to a direct current (DC) signal. The DC signal is used to operate each of the plurality of panels and the receiver circuit.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1B illustrate an embodiment of an LED display panel;

FIGS. 2A-2B illustrate a front-view of a multi-panel display, in accordance with an embodiment;

FIG. 3 illustrates an embodiment of a display system having display panels;

FIGS. 4A-4C illustrate embodiments of a data packet flow diagram configuration;

FIG. 5 illustrates a flow chart of an embodiment method for auto-scaling and self-configuration, as performed by a panel;

FIG. 6 illustrates a flow chart of an embodiment method for auto-scaling and self-configuration, as performed by a central device;

FIG. 7 illustrates an embodiment system diagram schematic of a panel;

FIG. 8 illustrates a diagram of an embodiment LED receiver circuit;

FIG. 9 illustrates an embodiment of the display system in which the data receiver box has minimal functionality;

FIG. 10 illustrates an alternative embodiment of the present invention;

FIG. 11 illustrates an alternative embodiment of the present invention in which each display panel has a unique IPV6 IP address; and

FIG. 12 illustrates an embodiment of LED panels and LED subpanels.

### DETAILED DESCRIPTION OF ILLUSTRATIVE EMBODIMENTS

This disclosure provides many applicable inventive concepts that can be embodied in a wide variety of specific contexts. The specific embodiments discussed are merely illustrative of specific ways to make and use the invention, and do not limit the scope of the invention.

In the following embodiments, exterior displays are used herein for purposes of example. It is understood that the present disclosure may be applied to lighting for any type of interior and exterior display.

In some applications, the display may be a billboard that displays a video or a picture of an advertisement. In another application, the display may be a large-screen television designed to accommodate a large venue, such as a stadium or a concert hall. The large-screen television may display a video feed of the event, specific highlights, a replay, or statistics, such as game or player stats to an audience attending the venue.

When displaying media on a large display that is made of smaller modular display panels, there is a specific relationship between what a particular modular display panel shows in relationship to the entire display. This relationship is based on the intrinsic property of that particular modular display panel, for example, number of LEDs, number of rows and columns of LEDs. Therefore, an image, video, or text that is to be shown on a display is scaled in accordance with the number of vertical and horizontal panels in the display. In other words, an image that is to be displayed on a modular display panel of the entire display is scaled to fully incorporate the size and shape of the modular display panel, where each panel in the display is responsible for showing a segment of the image. As a result, each modular display panel shows a portion of the image and the combination of the modular display panels recreates the image in full. The methods and devices in this disclosure provide embodiments for auto-configurable and auto-scalable panels in a display with minimum manual intervention.

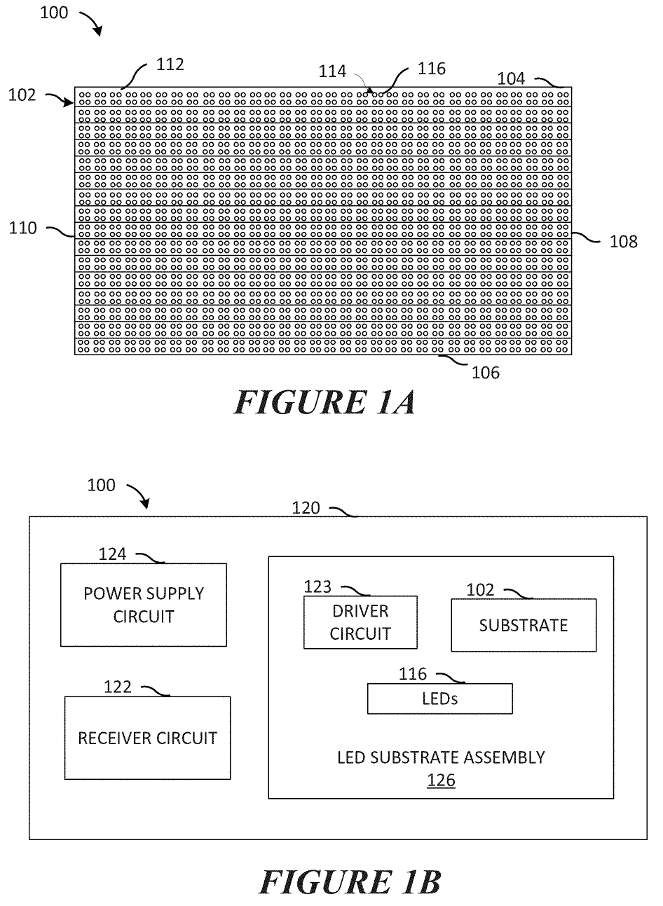

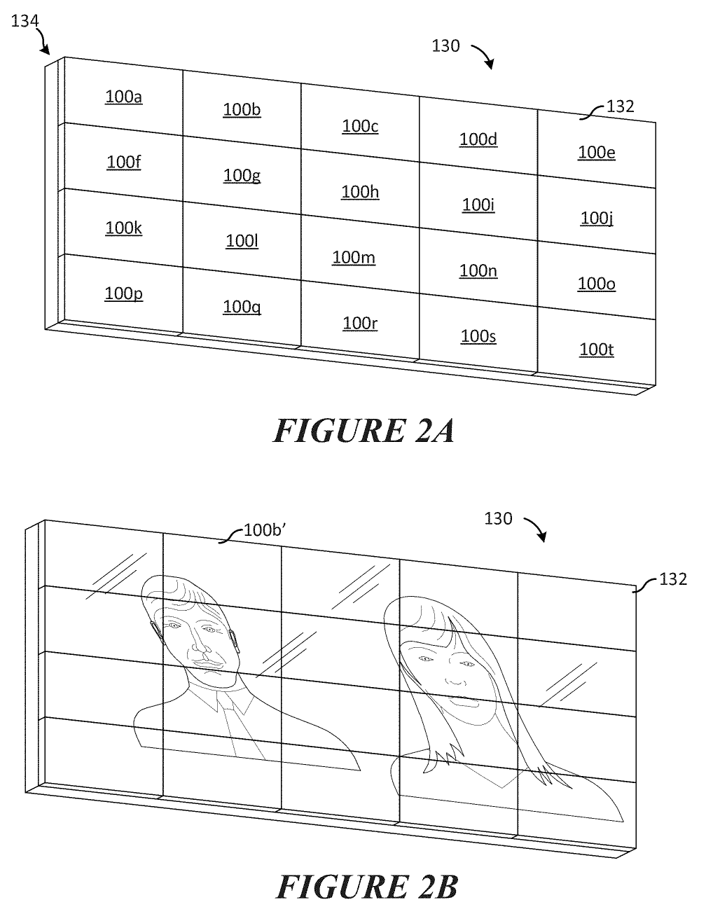

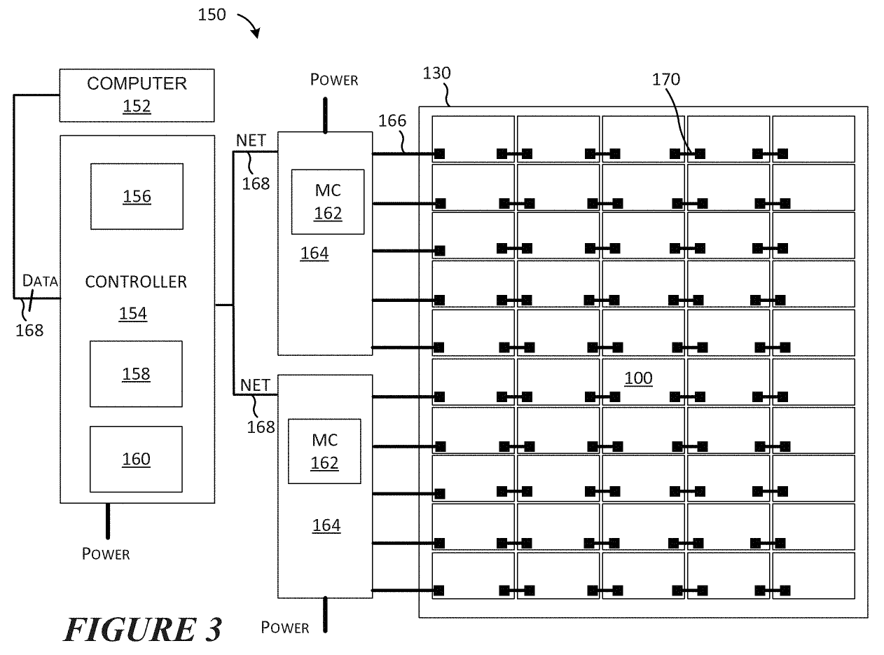

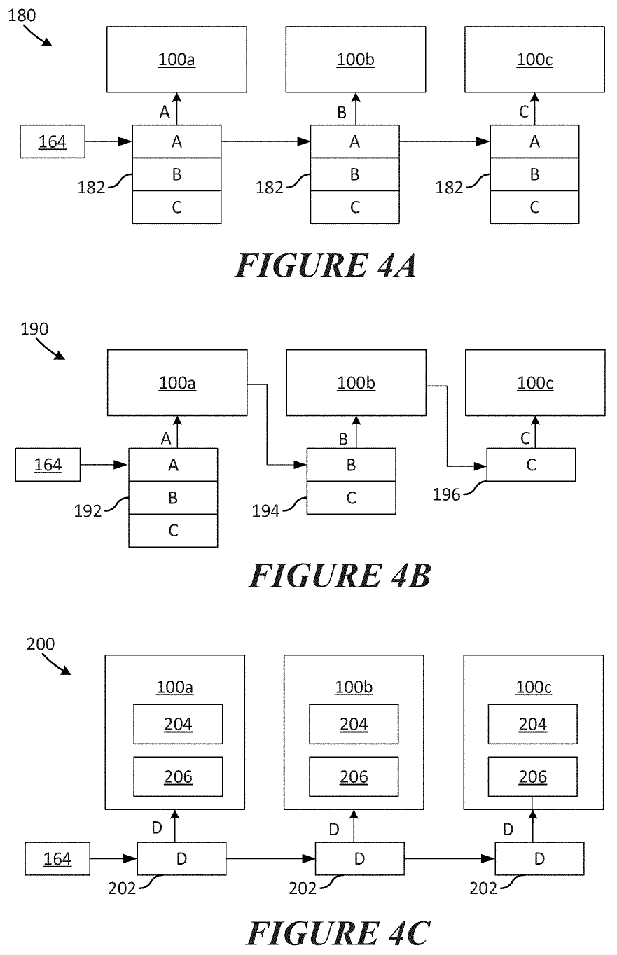

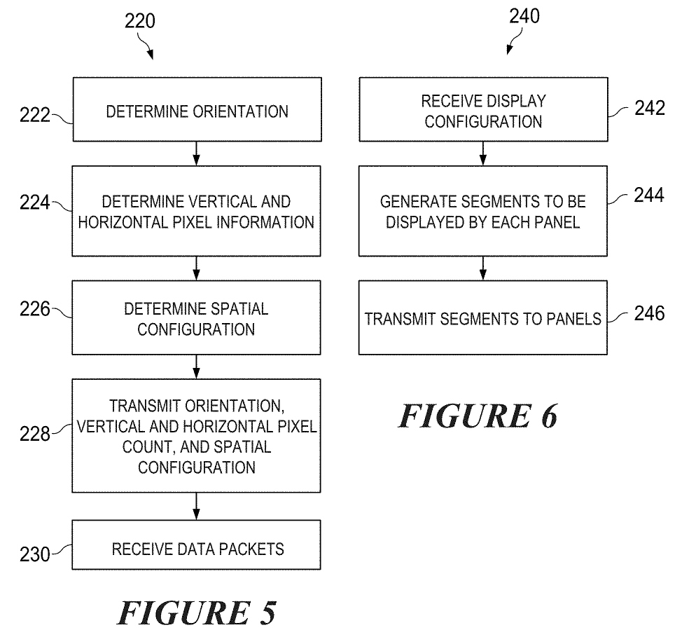

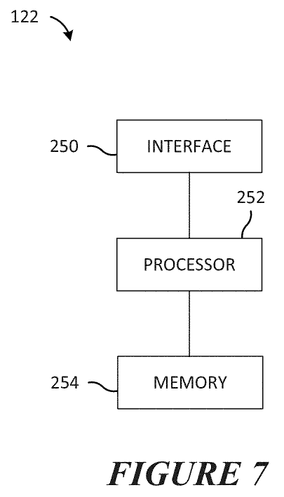

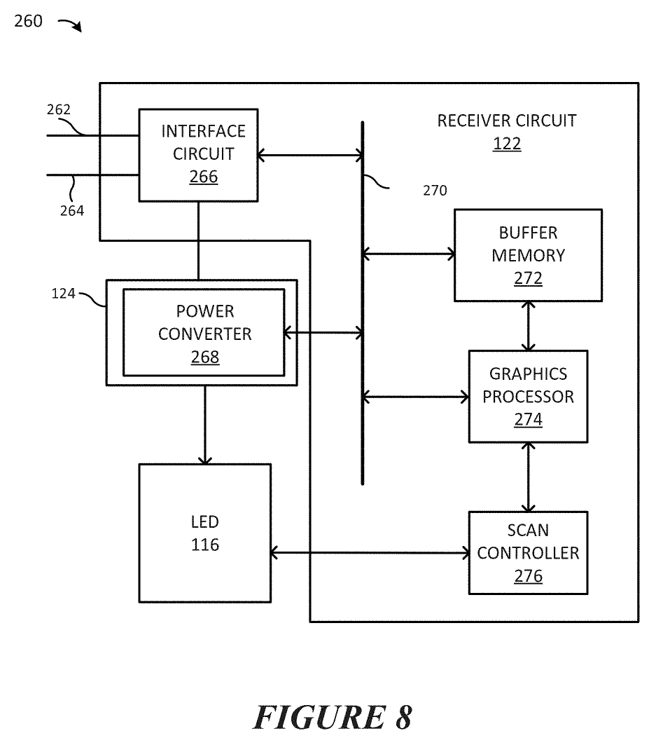

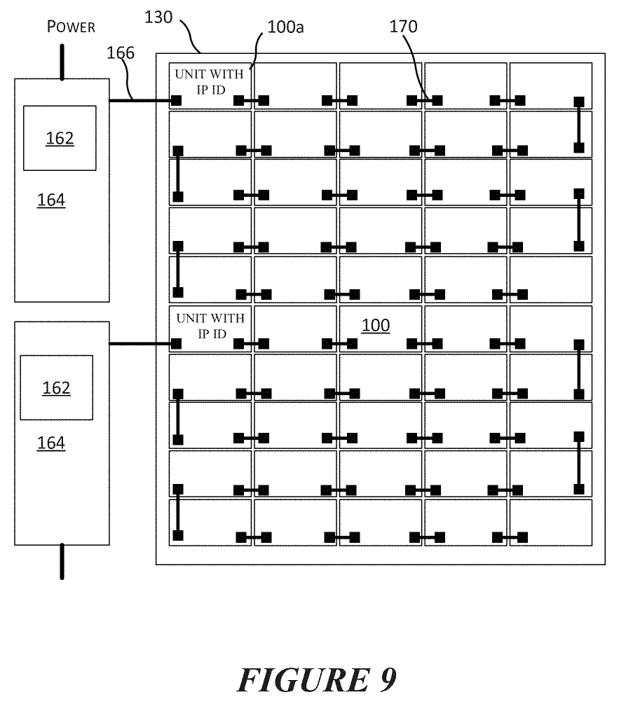

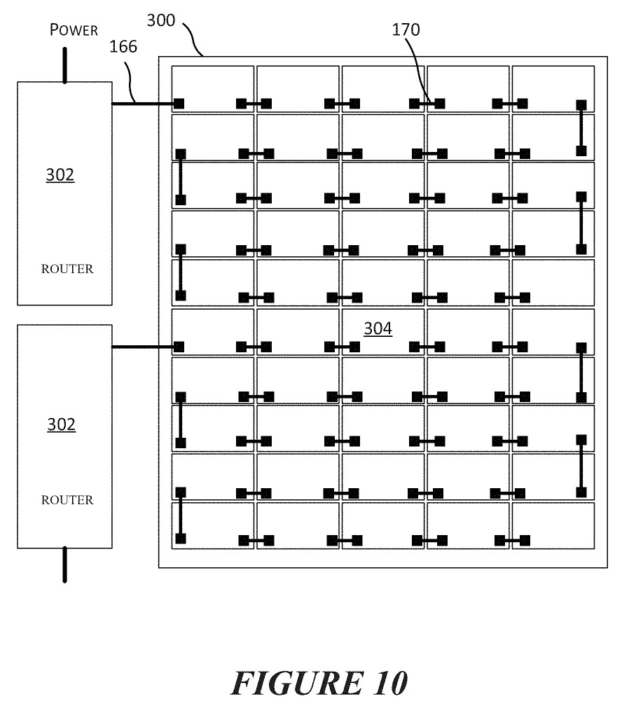

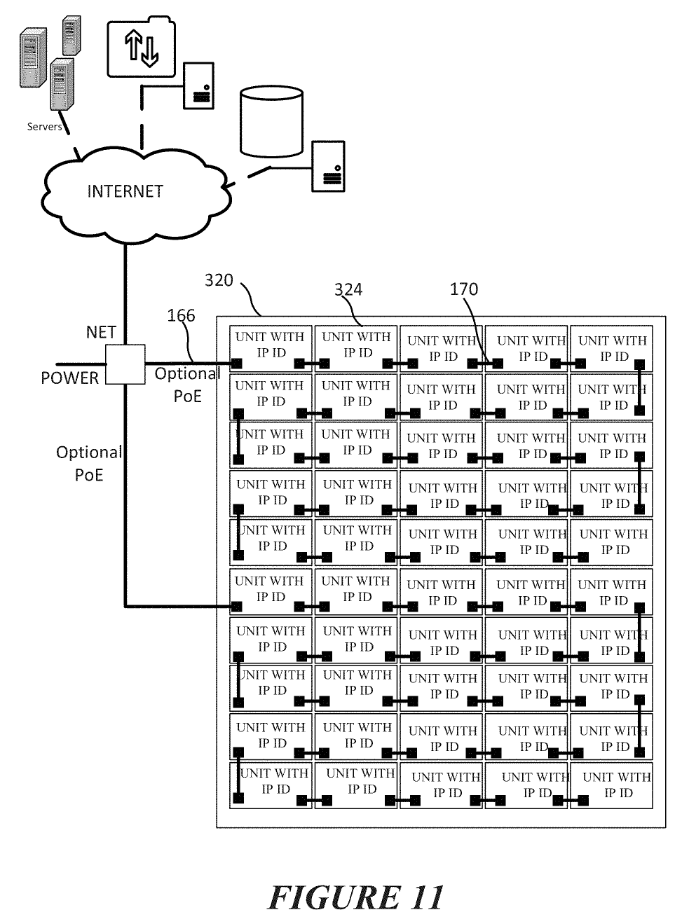

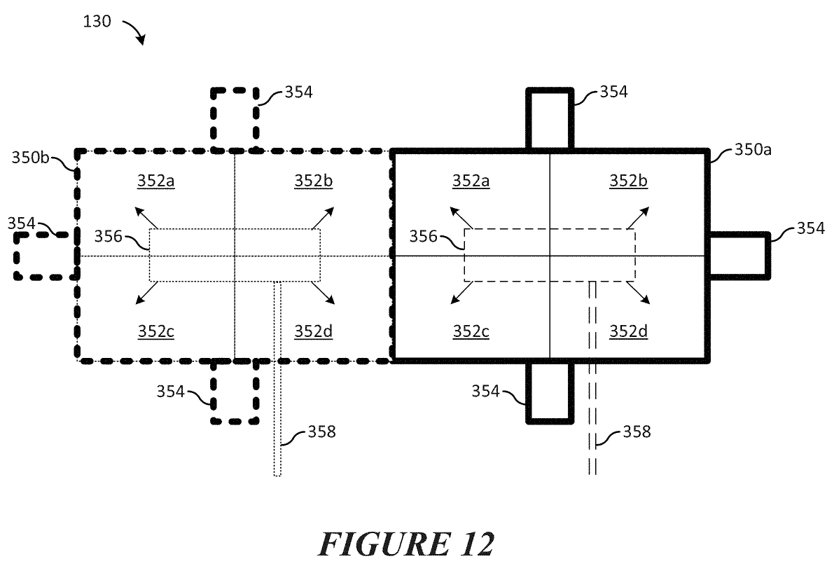

An embodiment of an LED display panel will be described using FIGS. 1A-1B. In FIGS. 2A-2B, a front-view of a multi-panel display, in accordance with an embodiment, will be described. An embodiment of a display system having display panels will be described in FIG. 3. In FIGS. 4A-4C embodiments of a data packet flow diagram configuration will be described. A flow chart of an embodiment method for auto-scaling and self-configuration, as performed by a panel, will be described in FIG. 5. In FIG. 6 a flow chart of an embodiment method for auto-scaling and self-configuration, as performed by a central device, will be described. An embodiment system diagram schematic of a panel will be described in FIG. 7. In FIG. 8 a diagram of an embodiment LED receiver circuit will be described. An embodiment of the display system in which the data receiver box has minimal functionality will be described in FIG. 9. In FIG. 10 an alternative embodiment of the present invention will be described. An alternative embodiment of the present invention in which each display panel has a unique IPV6 IP address will be described in FIG. 11. In FIG. 12 an embodiment of LED panels and LED subpanels will be described. In the following discussion, the same elements are designated with the same reference numbers in the various Figures.

FIGS. 1A-1B illustrate an embodiment of an LED panel 100. FIG. 1A illustrates a front view of a panel 100 and a substrate 102 aligned in a 16×32 configuration. FIG. 1B illustrates a block diagram of the components of the panel 100. The LED panel 100 in FIGS. 1A-1B are illustrative examples of a scalable and self-configurable panel in accordance with the methods and descriptions provided below.

Referring specifically to FIG. 1A, in the present example, the panel 100 includes the substrate 102, which may be a printed circuit board (PCB) on which the LEDs 116 are attached to form a front surface display. The substrate 102 is rectangular, with a top edge 104, a bottom edge 106, a right edge 108, and a left edge 110.

A substrate surface 112 includes “pixels” 114 that are formed by LEDs 116 mounted on the substrate 102. In the present example, each pixel 114 includes three to four LEDs 116 arranged in a pattern (e.g., square, circle). The four LEDs 116 that form a pixel 114 may include a red LED, a green LED, a blue LED, and optionally one other LED (e.g., a white LED). In some embodiments, the other LED may be a sensor. It is understood that more or fewer LEDs 116 may be used to form a single pixel 114, and the use of four LEDs 116 and their relative positioning as a square are for purposes of illustration only. In some embodiments, each pixel 114 has a lens protecting the LEDs as well as focusing the light from the LEDs onto a viewing plane. The lens may be designed to cover and focus red, green, and blue LEDs, for example.

As illustrated, the LEDs 116 may be of a dual in-line package (DIP) LED type. In DIP LED technology, the DIP LED may only display one color per device. As a result, a blue diode, a green diode, and a red diode are typically positioned proximate to each other to form a pixel. DIP diodes typically have a bullet shape design, are generally soldered to a printed circuit board (PCB), and may generate, for example, between 35 and 80 lumens per watt or be in a different range.

Alternatively, in some embodiments, the LEDs 116 may be of a surface-mount device (SMD) LED module type. In a SMD LED module, the LED module is a self-contained surface-mounted LED device that is usually mounted to a PCB. A SMD LED is typically less bulky in comparison with a DIP LED, generally having a flat design. As SMD LEDs have the Red Green Blue (RGB) capability on a single chip, an adjustment of the level output from each diode on the chip creates a desired output color. A typical SMD LED can, for example, produce between 50 and 100 lumens per watt or be in a different range.

Other types of LED technology, such as organic LEDs (OLEDs), edge emitting LEDs (ELEDs), chip on board (COB) and multiple chip on board (MCOB) type LEDs, can also be used in the LED panel 100. Therefore, in various embodiments, LEDs that produces light irrespective of the brightness can be used from any technology known to a person having ordinary skill in the art.

Referring to the schematic of FIG. 1B, the panel 100 includes a housing 120 that contains a receiver circuit 122, a power supply circuit 124, and an LED substrate assembly 126. The LED substrate assembly 126 comprises the LEDs 116 and a driver circuit 123 mounted on the substrate 102. The receiver circuit 122 supplies the requisite currents and voltages to the driver circuit 123 to illuminate the LEDs 116. The receiver circuit 122 may be configured to receive and process data and accordingly control the operation of the individual LEDs 116. As an example, the receiver circuit 122 may determine the color of the LEDs 116 to be displayed at each location (pixel). The power supply circuit 124 may be used to provide the proper voltages and currents for the LEDs 116 and the driver circuit 123.

The receiver circuit 122 may be a single chip or several chips mounted on a PCB, which may be different from the substrate 102 of the LED substrate assembly 126. The receiver circuit 122 may comprise a processor (e.g., field-programmable gate array (FPGA), application specific integrated circuit (ASIC)), a memory chips (i.e., dynamic random-access memory (e.g., DRAM) chip, buffer chip, etc.) interface chips (e.g., network handling, Ethernet transformer, power interface, etc.), switches, capacitors, resistors, and inductors.

In an embodiment, the receiver circuit 122 may receive digital packets or analog signals from an external computer or controller. The receiver circuit 122 may include a network receiver card for receiving data over a wide area network (WAN), local area network (LAN), or a wireless LAN (WLAN). The panel 100, using the receiver circuit 122, has the capability to receive input from a preceding panel 100 and provide an output to a succeeding panel 100. Each data and power cable connecting the panels 100 ends with an endpoint device or connector, which is a socket or alternatively a plug. The receiver circuit 122 may be configured to receive Transmission Control Protocol (TCP)/Internet Protocol (IP) data packets and decode, buffer, or perform other signal processing techniques on the received data packets to form an image.

In various embodiments, a driver circuit 123 is disposed within the substrate 102 of the LED substrate assembly 126. The driver circuit 123 is configured to control the LEDs 116. In various embodiments, a subset of the LEDs 116 have a dedicated driver circuit 123. The driver circuit 123 may also determine the brightness at each pixel 114 location, for example, by controlling the current supplied to the LEDs 116. In another embodiment, the brightness of the LEDs 116 may be controlled by turning the LED on and off via pulse-width-modulation (PWM). In some embodiments, the receiver circuit 122 may include the driver circuit 123. In some embodiments, both capabilities are designed into the receiver circuit 122.

Generally, the power supply circuit 124 is configured to provide a constant-current drive to the LEDs 116 and the driver circuit 123. In some embodiments, the power supply circuit 124 is configured to provide a constant Direct Current (DC) voltage to the LEDs 116 and the driver circuit 123.

In an embodiment, the power supply circuit 124 may comprise a power converter for converting Alternating Current (AC) to DC, which is then supplied to the LEDs 116. In an embodiment, the power supply circuit 124 converts a 240V or 120V AC to several volts DC up to in some cases 24V DC. As an example, a display panel may operate at 4.2 V DC, for example, 160 Watts to the LEDs 116 of the panel 100. Advantageously, a display panel can be designed to handle both 240V and 120V AC and therefore be compatible with worldwide power distributions.

In another embodiment, the power supply circuit 124 may comprise a down converter that down converts the voltage suitable for driving the LEDs 116. As an example, the down converter may down convert a DC voltage at a first level (e.g., 12V, 24V, or 48V DC) to a DC voltage at a second level (e.g., 4.2V DC) that is lower than the first level. Examples of down converters (DC-DC converters) include linear regulators and switched mode converters such as buck converters.

In some embodiments, the output from the power supply circuit 124 is isolated from the input power, also known as isolated converters. Accordingly, in various embodiments, the power supply circuit 124 may comprise a transformer. In another embodiment, the power supply circuit 124 may comprise forward, half-bridge, full-bridge, or push-pull topologies.

Each display panel 100 may have ports and mounting latches to connect to adjacent panels. In these embodiments, data and/or power may be received for only the panel 100 or may be passed on to one or more other panels. Accordingly, in some embodiments, the receiver circuit 122 and/or power supply circuit 124 may be configured to pass data and/or power to other panels. The control signals and external power may also be fed to each panel in a daisy chain or individually. In some embodiments, the panel may have a socket for registered jack (RJ) 45 standard interface. The RJ45 interface allows the display panel to receive signals digital packets or analog signals from an external computer.

In the present example, the housing 120 is sealed to prevent water from entering the housing 120. For example, the housing 120 may be sealed to have an ingress protection (IP) rating such as IP65 or higher, which defines a level of protection against both solid particles and liquids. In some embodiments, the panels have a IP protection rating of IP66, IP67, or IP 68. This ensures that the panel 100 can be mounted in inclement weather situations without being adversely affected. In such embodiments, the cooling may be passive as there are no vent openings for air intakes or exhausts. The housing 120 may be made of a thermally conductive material (e.g., aluminum, carbon fiber composite, titanium alloys, thermally conductive plastic) that is relatively light-weight and rigid. In a thermally conductive plastic, nonmetallic fillers are added to a thermoplastic, such as polyetheretherketone (PEEK), ABS, liquid-crystal polymers (LCP). Thermally conductive plastics provide uniform heat dissipation in a light weight package that additionally takes advantage of the design versatility provided, for example, with an injection molding manufacturing process.

FIGS. 2A-2B illustrate a front-view of a multi-panel display 130, in accordance with an embodiment. In FIG. 2A, the multi-panel display 130 (hereinafter referred to as a “display 130”) includes a display surface 132 formed by a plurality of lighting panels 100a-100t (hereinafter referred to as a “panel 100” or “panels 100”). The panels 100 and the display 130 in FIGS. 2A-2B are illustrative examples of a scalable and auto-configurable panel apparatus and display system in accordance with the methods and structures described below.

Each panel 100 of each row and/or column of the array of panels 100 is electrically connected to an adjacent panel 100 within that row and/or column. Each panel 100 of each row and/or column of the array of panels 100 is also physically connected to an adjacent panel 100 at one or more panel edges (104, 106, 108, and 110) in accordance with the spatial configuration of the panel 100 in the display 130.

In the present example, each of the panels 100 is attached to a frame 134, enabling the panels 100 to be installed or removed from the display 130 without affecting other panels 100. A first panel 100 can be coupled, for power and/or data purposes, with a second panel 100 that receives power and/or data from a central source or a third panel 100.

The second panel 100 may also pass through at least some of the power and/or data to a fourth panel 100. This further improves the modular aspect of the display 130, since a single panel 100 can be easily installed in the display 130 by coupling the power and data connections of the single panel 100 to neighboring panels 100. Similarly, a single panel 100 can be easily disconnected from the display 130 by decoupling the power and data connections of the single panel 100 from neighboring panels 100.

In some embodiments, the panels 100 are “hot swappable.” By removing a panel 100, using for example, screws in each of the four corners of the panel, servicing the display is fast and easy. Since a highly trained, highly paid electrician or LED technician is not needed to correct a problem, cost benefits can be achieved. As an illustration, the panel 100b of FIG. 2A is replaced with panel 100b′, which is illustrated in FIG. 2B. Upon completion of the hot swapping, the newly added panel 100b′ automatically configures itself so that the portion of the image that needs to be displayed by the panel 100b′ is identified, resized and scaled, and displayed correctly to produce the larger display as shown in FIG. 2B.

The power and data connections for the panels 100 may be configured using one or more layouts, such as a ring, mesh, star, bus, tree, line, or fully connected layout, or a combination thereof. In some embodiments the panels 100 may be in a single network, while in other embodiments the panels 100 may be divided into multiple networks. Power and data may be distributed using identical or different layouts. For example, power may be distributed in a line layout, while data may use a combination of line and star layouts.

As illustrated in FIG. 2B, the panels 100 typically operate together to form a single image across the display surface 132, although multiple images may be simultaneously displayed by the display 130.

In some embodiments, the display 130 may have panels 100 with different resolutions to achieve an optimal tradeoff between panel cost and image quality. As an example, with respect to FIGS. 2A-2B, the panels 100 in the bottom row may have a first resolution used for captions or other text; the panels 100 in the top row may have a medium resolution used for background portions of the image; and the panels 100 in the center row may have a high resolution used for showing a more detailed image.

FIG. 3 illustrates an embodiment of a display system 150 and its various components. FIG. 3 illustrates one way to implement the embodiment described in FIGS. 1A-1B and 2A-2B above. The monitoring controller 162 is configured to monitor power failure in one or more panels 100 and report to the computer 152 or to a different receiving monitoring server.

In various embodiments, the monitoring controller 162 is configured to monitor illumination or brightness of one or more panels 100. The monitoring controller 162 may also monitor the network between the data receiver box 164 and the outside internet 168 including computer 152 as well as the local area network 170 (or equivalent wireless network) connecting the individual panels 100 of the display 130.

In some embodiments, the data receiver box 164 may be mounted to a frame holding panels 100, such that a subset of the panels 100 share one data receiver box 164. The data receiver box 164 may transmit analog or digital video. As an example, the data receiver box 164 may output a composite video, a luminance-blue-difference-red-difference (YC_{B}C_{R}) analog component video, luminance-chrominance (YC) encoded analog video, red-green-blue (RGB) analog video, or an encoded digital video (e.g., 4:4:4 YC_{B}C_{R}, 4:2:2 YC_{B}C_{R}, 4:4:4 RGB, 4:2:2 RGB, etc.) to each of the panels 100 coupled to the data receiver box 164.

The computer 152 sends data via the network 168 to the controller 154. The controller 154 may comprise components to transmit data from the computer 152 to the data receiver box 164 via the network 168. In some embodiments, the controller 154 may comprise a card 156 configured to transmit data via a wireless or wired network 168. In some embodiments, the controller 154 may also comprise a microcontroller 158 to, for example, adjust resolution transmitted to the display 130. The controller 154 may also comprise a memory 160 that may be used to store the display configuration and/or the processor-executable instructions to be processed by the microcontroller 158. The memory 160 may be implemented as a non-transitory processor-readable medium. The non-transitory medium could include one or more solid-state memory devices and/or memory devices with movable and possibly removable storage media.

The monitoring controller 162 may also be used for other purposes. As an example, in one or more embodiments, the panels 100 may include one or more sensors to self-regulate operation based on external conditions. For example, the sensor may reduce or increase the brightness of the panels 100 based on ambient light. Alternatively, in some embodiments, the panels 100 may sense the presence of an observer (e.g., human) and modulate the content being displayed. For example, the display 130 may be powered off until a human approaches the display 130. In some embodiments, the monitoring controller 162 may also be used in combination with, or independently of, the panels 100 to determine the panel configuration or an event trigger, such as a change in panel configuration. As an example, a replaced panel may trigger a signal that is received at the monitoring controller 162. The monitoring controller 162 may determine, for example, the location of the panel in the display 130 and, in accordance with the methods described herein, initialize or configure the panel 100, the computer 152, the data receiver box 164, or the controller 154 to properly generate and display the segments of the image in accordance with the proper scale and configuration of the display 130.

In one or more embodiments, the first display panel 100a may include a monitoring circuit for monitoring the status of one or more panels being serviced by the first display panel 100a. As an example, the monitoring circuit may have switches (i.e., mechanical, automatic, etc.) at the panel edges or sensors (NFC, vicinity, inductive, etc.) that detect the removal and/or the installation of the panel or that of an adjacent panel. The action of the detection of a change may trigger, for example, an initialization or configuration of the panel 100.

FIGS. 4A-4C illustrate several data packet flow diagram configurations 180, 190, and 200, in accordance with embodiments of this disclosure. As previously discussed, a typical display 130 uses an array of panels 100, although an embodiment with three panels 100a-100c is contemplated. To simplify the discussion, the various data packets are said to have been transmitted from the data receiver box 164, however, other transmitting sources may also be contemplated. In addition to these flow diagram configurations, and combinations of these configurations, other panel configurations may also be contemplated. However, for the purposes of this discussion, three embodiments are disclosed.

An image, video, or text may be segmented into multiple segments or portions, to be displayed respectively at each panel 100a, 100b, and 100c, in accordance with the configuration information of the display system 150. The image, video, or text may be segmented at the computer 152, at the controller 154, at the data receiver box 164, at the receiver circuit 122, or at another device configured to generate the segments.

In FIG. 4A, in an embodiment, a sequence of data packets 182 are transmitted to each of the panels 100a-100c from the data receiver box 164. The sequence of data packets 182 can be transmitted directly to each panel 100 or forwarded along the distribution chain from one panel to the next.

In this embodiment, the configuration information of the display system 150, for example, the number of panels 100, the aspect ratio of each panel 100, the pixel density of each panel 100, the spatial configuration of each panel 100, etc. may be stored in a memory of the computer 152, the controller 154, or the data receiver box 164. The computer 152, the controller 154, or the data receiver box 164, individually or in combination, may utilize this configuration information to generate the many segments or the many portions to be transmitted to and to be displayed by each panel 100a-100c. The mapping of these segments is determined at the computer 152, the controller 154, or the data receiver box 164 and transmitted to the panels 100 in a corresponding header for each data segment.

Each data packet, in the sequence of data packets 182, comprises a payload and a header. The header information may identify the source and the destination of the packet payload, payload size, payload resolution, payload format/protocol, checksum, or other metadata used to route and deliver the payload. The source and destination address of the packet payload may be identified, for example, using an internet protocol (IP address) or a media access control address (MAC address).

The packet payload is the data, in the form of an image, video, or text. Each panel 100a-100c displays a segment of an image contained within a corresponding payload, using the header information; panel 100a displays payload A; panel 100b displays payload B; and panel woe displays payload C.

Each panel receives the sequence of data packets 182 and is configured to, in accordance with the header information in each data packet, determine whether it is the intended destination of the data packet in the sequence of data packets 182. In the event that the panel 100 determines that it is the intended destination of a data packet, the panel 100 displays an image contained within the corresponding data payload.

In an another embodiment, the sequence of data packets 182 are transmitted to each of the panels 100a-100c from the data receiver box using one or more data channels of the local area network (LAN) 170 through a multiple access technique such as packet addressing or time division multiplexing. In this configuration the destination panel assigned to each data packet is identifiable. Prior to the transmission of the sequence of data packets 182, panels 100a-100c are initialized, using a control channel, by providing the receiver circuit 122 of the panels 100a-100c with a unique address, time slot number (TSN), or other identifying information that is stored in a memory of the panels 100a-100c.

In some embodiments, a destination address is inserted by the data receiver box 164 into the header of each of the data packets. In other embodiments, a video segment intended for one of panels 100a-100c is inserted by data receiver box into a time slot in the data stream in accordance with a TSN assigned to the destination panel. In other embodiments, the data receiver box 164 indicates, using a control/address signal on the control channel, which panel should be actively receiving the corresponding data packet in the sequence of data packets 182. An interface circuit 266, explained further-below, in each panel 100a-100c determines, in accordance with the control/address signal or the address or TSN stored in its memory, whether the data packet received is intended for panel 100a, 100b, or 100c.

In FIG. 4B, in another embodiment, a first sequence of data packets 192 is transmitted to panel 100a from the data receiver box 164. Similar to the data packet configuration illustrated in FIG. 4A, the computer 152, the controller 154, or the data receiver box 164 are configured to generate the segments to be displayed by each panel 100a-100c. However, in the embodiment of FIG. 4B, the computer 152, the controller 154, or the data receiver box 164, individually or in combination, are configured to generate the first sequence of data packets 192 and to arrange the data packets in a predetermined order in accordance with the data distribution layout of the display 130.

As illustrated, the first panel 100a receives the first sequence of data packets 192. Panel 100a is configured to display the first data packet (i.e., payload A) in the first sequence of data packets 192. Panel 100a is also configured to generate a second sequence of data packets 194 corresponding to the first sequence of data packets 192 minus the first data packet (i.e., payload A). Panel 100b is configured to receive the second sequence of data packets 194, display the second data packet (i.e., payload B) in the second sequence of data packets 194, and generate a third sequence of data packets 196 corresponding to the second sequence of data packets 194 minus the second data packet (i.e., payload B). This process is repeated by each receiving panel along the data distribution chain.

Thus, each panel 100a100b, and 100c respectively receives a sequence of data packets 192, 194, and 196, forwards an updated sequence of data packets minus the first data packet in the sequence that it had originally received, and displays the segment of an image contained within the payload of the first data packet it had received.

Each panel may have a delay interval, for example using one or more buffer chips or memory chips, to account for the delay incurred for processing and transmitting the sequence of data packets along the data distribution path. The delay interval provides the requisite time to synchronize the display of the segments by each panel 100 in the display 130.

As an example, in an embodiment, the number of data packets in the sequence of data packets, received by a panel along the data distribution path, is reduced by one. A delay interval equal to the number of packets in the sequence of packets that is to be forwarded may be used as the delay interval for each panel. Thus, each panel may store a delay value corresponding to the number of data packets that are forwarded in a memory and delay the display of the segment in accordance with that delay value.

In another embodiment, a frame clock, latch signal, or other control signal provided by the data receiver box 164 may signal panels 100a-100e to display the local video frames stored in their buffer memories. In an embodiment, multi-pin connections can be used to support signaling in the channels between the data receiver box 164 and the panels 100a-100c. An exemplary 16-pin connection includes a latch pin, a clock pin, five address pins, an enable pin, three data pins, a signaling voltage pin, a signaling ground pin, a power supply pin, a power return pin, and a power ground pin. More or fewer pins may be provided for any of the foregoing pin types, and not all pin types may be provided in a multi-pin connection.

Advantageously, as the data distribution layout and the arrangement of the sequence of data packets from the data receiver box 164 dictate what is to be displayed by a panel 100, the panels 100 do not require individual configuration.

In FIG. 4C, in yet another embodiment, a data packet 202 is transmitted to each of the panels 100a-100c from the data receiver box 164. Unlike the embodiments in FIGS. 4A and 4B, the computer 152, the controller 154, or the data receiver box 164 do not generate the many segments. The data receiver box 164 transmits the data to be displayed, in its entirety, to each panel 100a-100c. Each panel 100 is configured to generate a corresponding segment of the data in the data packet 202 in accordance with the panel's spatial configuration. The spatial configuration of the panel 100 may be stored at a memory 206 of the panel 100 and processed by a processor 204 in the panel 100. Alternatively, the spatial configuration may be stored at the computer 152, the controller 154, or the data receiver box 164 and communicated to each panel 100 using an identifying tag within a header.

The panels 100a-100c may be a smart panel, each having an assigned MAC and/or IP address. Each smart panel is programmed with a set of instructions stored on the on-board memory 206 during panel production or received from the data receiver box 164, for example, at panel initialization or prior to transmitting the image by the display 130. Each panel may also receive information from, for example, the data receiver box on the division of the display 130 to show several image feeds simultaneously. As an example, a top portion of the display 130 may be configured to show one image while the panels at the bottom row may be configured to show a text at a same time. In some embodiments, each panel can receive the image, video, or text and any other display 130 arrangement and determine the segment of the image that is to be shown.

In a typical panel installation or a panel upgrade, an operator manually or remotely configures the panels 100, the computer 152, the controller 154, and the data receiver box 164 in the display system 150 to display the image, text, or video at each panel 100. In addition, when one or more panels, but not necessarily all of the panels in the display 130, are replaced, the computer 152, the controller 154, the data receiver box 164 and/or each panel 100 may also be reconfigured for proper image display. Embodiments of this disclosure provide an auto-scalable and a self-configurable panel in a display system 150 that reduces assembly cost and assembly time during a first assembly and during a panel upgrade.

FIG. 5 is a flow chart 220 of an embodiment method for auto-scaling and self-configuration, as may be performed by a panel 100 in a display system 150. Initially at step 222, the orientation of a panel 100 is determined. The panel 100 may be oriented in landscape mode or portrait mode. In landscape mode, the width of the panel 100 is greater than the panel height. Alternatively, in portrait mode, the height of the panel 100 is greater than the panel width. In some embodiments, sensors, such as an accelerometer, a tilt sensor, a gyroscope, or a magnetometer (magnetic field sensor or geomagnetic field sensor), may be used to determine panel orientation. In some other embodiments, an automatic mechanical switch or a manual switch, for example located at the panel edge, may be automatically or manually activated and used to determine panel orientation. In other embodiments, a combination of the above-mentioned sensors and switches can be used to detect panel orientation.

At step 224, the total number of vertical and horizontal pixels of each panel 100 is determined. In one embodiment, the total number of vertical and horizontal pixels may be stored in a memory 206 of a panel 100. In another embodiment, the number of vertical and horizontal pixels may be known based on the panel model type chosen for the display system 150. In other embodiments, the number of vertical and horizontal pixels may be manually entered by an operator.

At step 226, the panel spatial configuration within the display 130 is determined. In a typical installation, the data distribution path, the path used to communicate data from the data receiver box 164 to each of the panels 100 (i.e., data distribution layout), is known. As an example, in some embodiments, the manufacturer may instruct installers to assemble the panels 100 in a certain configuration through assembly instructions. In some other embodiments, the panels and the display 130 may be designed such that the distribution of data follows an explicitly defined path.

In some embodiments, each panel, using sensors and/or switches, may determine if and optionally which panels are situated at each of its panel edges 104, 106, 108, and 110. For example, referencing FIG. 2A, panel 100a may determine that panel 100b is located at the right edge 108 and panel 100f is located at the bottom edge 106. As an example, each panel may be outfitted with near field communication (NFC) sensors, vicinity sensors, pressure sensors, or induction loop panel detectors, at its one or more edges.

As another example, each panel may transmit a packet comprising a panel identifier, information related to the panel edges (i.e., no panels at the edges, one panel at the top edge 104, etc.), and a panel offset value that includes the number of panels horizontally, vertically, or the total number of panels that separate the panel 100 from the data receiver box 164. In an embodiment, referencing FIG. 2A and in a strictly horizontal data distribution configuration, data packets are transmitted from panel 100a to panel 100e, from panel 100f to panel 100j, from panel 100k to panel 100o, and from panel 100p to panel 100t. Panels 100a, 100f, 100k, and 100p are originating panels, panels 100e, 100j, 100o, and 100t are end point panels, and the remaining panels are intermediary panels. Each panel 100 is configured to transmit a packet comprising a panel identification number (i.e., serial number) to a neighboring panel in the reverse direction of the distribution chain. Each receiving panel 100 increments an offset value that is also included in the packet. The packet is again forwarded in the reverse direction until it reaches the originating panel 100a, 100f, 100k, and 100p. This information may then be stored at each of the originating panels or transmitted back to the corresponding panel 100. In some embodiments, the round-trip travel time in a panel for a data packet to traverse the length of the data distribution to, for example, the originating panel may be determined using a ping technique.

In another embodiment, each panel 100 may individually determine which panels are located to its left, right, bottom or top edge location (i.e., using NFC sensors) and store this information in a memory 206. Each panel 100 may then transmit this information to a central device (i.e., data receiver box 164, master panel, originating panel, etc.). The central device, using the collective information collected from the panels (panel orientation, panel edge information, distance from the data receiver box 164, etc.), may then determine the overall display configuration and spatial configuration of each panel. This information may be stored at the central device or transmitted back to each individual panel 100.

At step 228, each panel 100 transmits its corresponding orientation, the vertical and the horizontal pixel count, and, optionally, the spatial configuration information to the data receiver box 164.

At step 230, each panel 100 receives a data packet comprising a header and a payload to display the image, video, or text.

FIG. 6 is a flow chart 240 of an embodiment method for auto-scaling and self-configuration, as may be performed by a central device (i.e., computer 152, a controller 154, data receiver box 164) in a display system 150. Initially, at step 242, the central device receives, from each panel in the display 130, a corresponding panel orientation, panel vertical and horizontal pixel count, and spatial configuration.

At step 244, the central device, uses the information from step 242, such as the total number of panels, total number of vertical and horizontal panels, location of each panel in the display, and panel specific information, such as panel pixel dimensions, orientation, etc. to generate the segments to be displayed by each panel. Each segment is then contained within a data packet as a packet payload. A header of the packet comprises information detailing the destination panel. As an example, a panel identification tag in the header may be used by each panel 100 to determine whether it is the intended destination of the data packet.

At step 246, the central devices transmits the data packets in accordance with the data packet flow diagram and the display system 150 configuration, which may be a ring, mesh, star, bus, tree, line, or fully connected layout, or a combination thereof.

In some embodiments, one or more steps in FIG. 5 and 6, respectively of the panel 100 and the central device, may be optional or shared between the components. As an example, with respect to the packet transmission of FIG. 4C, the data receiver box 164 may send the entire data to be displayed to each panel. Each panel, using the processor 204, in accordance with the spatial configuration stored in memory 206, generates the segments to be displayed. Alternatively, the panel 100 may receive instructions from the data receiver box 164 to generate the corresponding segment. In this arrangement, the steps to generate the segments are shared between the computer 152, the controller 154, the data receiver box 164, and/or the panel 100.

This proposed self-automated and self-configured display system 150 reduces installation time and can replace intensive manual steps that add cost and may delay product assembly. In the instance where a panel is first installed or replaced, for example during an upgrade or to correct for a panel issue, the steps above may be automatically performed by the computer 152, the controller 154, the data receiver box 164, and/or the panel 100 as an initialization routine of the display 150.

The initialization trigger can be the supply of power to the panel or flagged during power down to be initiated during reboot. Alternatively, the trigger can be a manual initialization request upon completion of the panel replacement. In an alternative arrangement, a panel may determine using, for example, a sensor that an edge panel has been swapped. The panel can then send an initialization request to the data receiver box 164. In yet another embodiment, the computer may request a handshake request from each panel upon successfully receiving instructions embedded in the packet header. If the computer does not receive the handshake return, from one or more panels, the computer can initiate the initialization routine.

FIG. 7 illustrates a block diagram of an embodiment receiver circuit 122 for performing methods described herein. As shown, the receiver circuit 122 includes a processor 252, a memory 254, and an interface 250, which may (or may not) be arranged as shown in FIG. 7. The processor 252 may be any component or collection of components adapted to perform computations and/or other processing related tasks, and the memory 254 may be any component or collection of components adapted to store programming and/or instructions for execution by the processor 252. In an embodiment, the memory 254 includes a non-transitory computer readable medium. The interface 250 may any component or collection of components that allow the receiver circuit 122 to communicate with other devices/components and/or a user. For example, the interface 250 may be adapted to communicate data, control, configuration, or management messages from the computer 152, the controller 154, or the data receiver box 164 to the receiver circuit 122. The receiver circuit 122 may include additional components not depicted in FIG. 7, such as long-term storage (e.g., non-volatile memory, etc.).

FIG. 8 illustrates a system diagram schematic 260 of the panel 100 in accordance with an embodiment of the present invention. FIG. 8 may be a specific implementation of the embodiment of FIG. 7. The receiver circuit 122 comprises an interface circuit 266, a receiver bus 270, a buffer memory 272, a graphics processor 274, and a scan controller 276. The power supply 124 comprises an power converter 268.

The panel 100 receives data and power signals at the input cable 262. Another output from the incoming power may be provided to the output cable 264. This may provide redundancy so that even if a component in the panel 100 is not working, the output power is not disturbed. Similarly, the output cable 264 includes all the data packets being received in the input cable 262. The incoming power is provided to the components of the panel 100, such as the power supply 124 and the power converter 268.

The power and data cables 262, 264 include wires for carrying data/control information and wires for carrying power, which may be integrated. The data/control wires may be of the twisted pair variety. In some embodiments, the power and data cables are not integrated and several cables may be required to transmit the data and power signals (not shown). The length of the data and power wires may be controlled to provide signal propagation within each panel 100 within a specific time. The data/control wires may be configured to transport data at a high bit rate, e.g., at least 1 Mbit/s, and may be 100-1000 Mbit/s. To minimize noise, the cable as a whole may be shielded or the data/control wires or twisted pairs of data/control wires may be shielded separately. In some embodiments, the power connections to the power wires can be configured so that power is run across all of a row (or any other group of panels). In this manner, if the power supply of any one of the panels fails, the other panels will continue to operate.

The data and power signal received at the input cable 262 is processed at the interface circuit 266. The interface circuit 266 provides received data packets to the graphics processor 274 through the receiver bus 270. In some embodiments, the interface circuit 266 provides only the data packets intended for the panel 100. In other embodiments, the interface circuit 266 provides all incoming data packets to the graphics processor 274. For example, in some embodiments, the graphics processor 274 may perform decoding of the received media. The graphics processor 274 may use the buffer memory 272, or frame buffer, as needed to store media packets during processing. The graphics processor 274 may perform additional signal processing techniques on the packets, such as decrypting, to provide the necessary signals for displaying the image for the panel 100. In an embodiment, the interface circuit 266 may determine the panel configuration, in accordance with the methods described. The interface circuit 266 may then store the panel configuration in the buffer memory 272 or transmit the panel configuration to, for example, the data receiver box 164.

In some embodiments, the buffer memory 272 may be used to temporarily store the segments of the image until the receiver circuit 122 collects enough data for simultaneous display. The collected data may be a video frame for simultaneous display by all of the LEDs of the display panel, or it may be a smaller portion of data for display by a subset of the LEDs in accordance with, for example, a scanning pattern. The buffer memory 272, may also be used as a temporary storage of segments destined for other display panels.

A scan controller 276, which may include an address decoder (e.g., a de-multiplexer), receives the media to be displayed, and identifies individual LEDs that need to be controlled. The scan controller 276 may determine an individual LED's color, brightness, refresh time, and other parameters associated to generate the display. In an embodiment, the scan controller 276 may include control circuitry, such as a row selector and a column selector, for determining the LED parameters. The scan controller 276 may provide the LED parameters to a driver circuit, which acts as either a current source or a current sink, to select the appropriate current for the particular LED. The driver circuit may either be a component of the scan controller 276 or may be located outside the scan controller 276 at, for example, the power supply 124.

Alternatively, in an embodiment, the scan controller 276 may interface directly with the LEDs 116. For example, the power converter 268 provides a constant current to the LEDs 116 while the scan controller 276 controls the select line needed to turn ON or OFF a particular LED. Further, in various embodiments, the scan controller 276 may be integrated into the power converter 268.

Various embodiments of the disclosed systems and methods can be applied to a panel 100 that is rated to IP 65 or higher and therefore waterproof and corrosion resistant. Because weather is the number one culprit for damage to LED displays, and IP 65 or higher rating provides weatherproofing with significant weather protection.

In one embodiment, these panels are completely waterproof against submersion in up to 3 feet of water (IP 67). In other embodiments, the equipment can be designed with an IP 68 rating to operate completely underwater. In lower-cost embodiments, the panels can have an IP 65 or IP 66 rating. A panel 100 enclosure rated to an IP X5 rating protects the panel 100 from water jets projected by a nozzle (6.3 mm) from any direction. A panel 100 enclosure rated to an IP X6 rating protects the panel 100 from powerful water jets projected by a nozzle (12.5 mm) from any direction. A panel 100 enclosure rated to an IP X7 rating protects the panel 100 from immersion up to 1 meter. A panel 100 enclosure rated to an IP X8 rating protects the panel 100 from immersion beyond 1 meter. A panel 100 rated to the IP X8 rating is hermetically sealed, however, in some types of equipment water may enter but only if it does not harm the device.

A panel 100 enclosure rated to an IP5Y rating limits ingress of dust into the panel 100 such that dust does not interfere with typical satisfactory operation, whereas a panel 100 enclosure rated to an IP6Y rating completely protects the panel 100 from ingress of dust. The panel 100 enclosure may be designed for the dust or water resistance of the environment that it is deployed. As an example, a billboard deployed in a dry environment does not necessarily need to be rated at IP X8 for proper functioning.

Additionally, the disclosed systems and methods can be applied to a panel 100 that is rated to operate in extreme temperature conditions. As an example, the enclosures and the display panels can operate at operating temperatures up to 200 degrees Celsius and as cold as −60 Celsius.

A person of ordinary skill in the art may understand that all or some of the processes of the methods in the embodiments may be implemented by a computer program instructing relevant hardware. The program may be stored in a computer-readable storage medium. When the program runs, the processes of the methods in the embodiments are executed in the processor.

FIG. 9 illustrates an embodiment of the display system 130 in which the data receiver box 164 (described earlier, e.g., FIG. 3) has minimal functionality or optionally skipped. The data receiver box 164 may simply connect the first display panel of the display system 130 with an interconnect (TCP/IP) port. The first display panel may include an identifier for the whole system so that the display system 130 advertises a single IP address. For example, the IP address of the display system 130 may be identified from the first display panel 100a. The remaining panels 100 may be daisy chained.

The media processing chip within each display panel 100 identifies and processes the correct media that is to be displayed from the data stream that includes all the media for all the panels in the chain.

The first panel in the series of panels includes a unique IP address. Thus, when connected to the internet, the network card at the first display panel 100a receives the data to be displayed by all the panels within the same series. The remaining panels use the data processed through the common network card at the first network. The remaining panels have to be configured/initialized so that they know which portion of the data is to be displayed by that particular unit.

FIG. 10 illustrates an alternative embodiment, of a router 302 is coupled between the display panels 304 and the internet. The router 302 may be coupled to a plurality of display panels 304, where each panel has its own network interface card each thereby having its unique MAC address.

In some embodiments, the first display panel may include the router 302, i.e., the router 302 may be integrated into the first display panel. The devices within the local area of the router may now be individually addressed using the display panels' 304 respective MAC address. Accordingly, packets destined to each panel are routed by the router 302. In this embodiment, the display panels 304 within a single display system 300 may be served from different locations. For example, a larger part of the screen may show an advertisement from a media server whereas a lower portion may show the temperature from a weather server or a sports score from a sport network server.

In one or more embodiments, each of the display panels 304 may include a monitoring circuit for monitoring the status of one or more panels as discussed above, for example, while describing FIG. 9.

FIG. 11 illustrates an alternative embodiment of the present invention in which each display panel 324 of the display system 320 has a unique IP address, for example, an IPV6 IP address. The media to be displayed may be split at the source of a single media server or may be obtained from multiple media server through the internet. For example, different portions of the display system 320 may be leased to a different company displaying its own content. This embodiment enables multiple users to share a single display board. For example, an expensive display location may be shared in time or space by multiple companies reducing their costs while improving effectiveness of the display. The display panels may be powered individually or through Power over Ethernet technologies using cat5, cat6 cables.

In one or more embodiments, each of the display panels 324 may include a monitoring circuit for monitoring the status of one or more panels as discussed above, for example, while describing FIG. 9. In various embodiments, upon replacement of a defective panel, the newly added panel may be triggered to generate position information relative to other panels and send the determined position information to a media server sending the media to be displayed on the display system 320. The media server can then tailor the image being sent based on the received information and transmit the image based on the unique IPV6 IP address directly to the newly added panel.

FIG. 12 illustrates an embodiment of LED panels 350a-350b and LED subpanels 352a-352d in a display 130. In this embodiment, each panel 350a-350b includes one or more subpanels 352a-352d. Each subpanel 352a-352d is similar in function and design to the panels 100 in the previous Figures. The subpanels 352a-352d in each panel 350a-350b share a common data receiver box 356. The common data receiver box 356 is similar in function and design to the data receiver box 164 in, for example, FIG. 3. The common data receiver box 356 receives power and data from an external source using the shared power and data cable 358 and transmit power (e.g., DC power) and data to the individual subpanels 352a-352d.

In FIG. 12, each panel 350a-350b and each subpanel 352a-352b may be removed and replaced without interference or impact to the surrounding panels and subpanels. In an embodiment, the action of removing and replacing of a panel or a subpanel may trigger, as previously described, for example, with respect to FIG. 3, an initialization or reconfiguration sequence for one or more of the panels 350a-350b and/or the subpanels 352a-352d. In another embodiment, the action of removing and replacing of a panel or subpanel may flag a change in configuration that may be later verified prior to initiating a panel or subpanel reconfiguration or initialization. In some embodiments, the action of removing and replacing of a panel or subpanel may create a temporary flag at a storage device in the panel 350a-350b, the subpanel 352a-352d, or the common data receiver box 356 and in combination with another trigger (i.e., power-up, power-down, system health check, etc.) will initialize or reconfigure the panels 350a-350b, subpanels 352a-352d, and/or the common data receiver box 356.

The common data receiver box 356 may be assigned a unique TCP/IP address and/or have a unique MAC address to communicate with each panel 350a-350b, subpanel 352a-352d, common data receiver box 356, and/or the external devices connected to the display 130. The common data receiver box 356 may receive the image segments or the full image through the power and data cable 358 and, in accordance with the methods previously described, may forward, or transmit the appropriate segments or the entire image to each of the subpanels 350a-350b coupled to the common data receiver box 356. In some embodiments, the common data receiver box 356, shared between the several subpanels 352a-352d, may operate, and manage the data to be transmitted to each subpanel 350a-350b independently of the subpanels 352a-352d in accordance with the methods described herein. In some embodiments, the common data receiver box 356 and the receiver circuit 122 (see FIG. 1B) in each subpanel 352a-352d in combination may determine the segments that are to be displayed by each subpanel.

In an embodiment, the power received from the external power supply may be in an alternating current (AC) format. The common data receiver box may convert the AC power to a direct current (DC) format using, for example, a rectifier (half-wave rectifier, full-wave rectifier, bridge rectifier, etc.) circuit in the common data receiver box 356. Alternatively, in some embodiments, the common data receiver box 356 may receive DC power and, optionally, down-convert the DC voltage to an operating voltage of the panels 350a-350b, the subpanels 352a-352d, and the common data receiver box 356. The DC-to-DC converters may be non-isolated (e.g., step-down (buck) converter, a true buck-boost converter, a split-pi (boost-buck) converter, etc.) or isolated (e.g., a forward converter, a push-pull converter, flyback, etc.). The converters may be selected to increase efficiency in the DC-to-DC conversion and therefore reduce heat generated in the form of conversion loss. An example of a high efficiency and low level EMI emitter is a LLC resonant full-bridge converter. Commonly owned U.S. patent application Ser. No. 15/793,333 ('333 Application) discloses several types of AC to DC and DC-to-DC converter circuits . The '333 Application is incorporated herein by reference.

The shared power and data cable 358 includes wires for carrying data/control information and wires for carrying power, which may be integrated. The data/control wires may be of the twisted pair variety. In some embodiments, the power and data cables are not integrated and several cables may be required to transmit the data and power signals (not shown). The length of the data and power wires may be controlled to provide signal propagation within each panel 350a-350b and each subpanel 352a-352d within a specific time. The data/control wires may be configured to transport data at a high bit rate, e.g., at least 1 Mbit/s, and may be 100-1000 Mbit/s. To minimize noise, the cable as a whole may be shielded or the data/control wires or twisted pairs of data/control wires may be shielded separately. In some embodiments, the power connections to the power wires can be configured so that power is run across all of a row (or any other group of panels). In this manner, if the power supply of any one of the panels fails, the other panels will continue to operate.

While it is understood that each panel 350a-350b may employ multiple subpanels 352a-352d coupled to the shared data receiver box 356, only four subpanels and two panels are illustrated for simplicity in FIG. 12.

Example embodiments of the present invention are summarized here. Other embodiments can also be understood from the entirety of the specification and the claims filed herein.

Example 1. A method for configuring a modular display system includes attaching a panel to form the modular display system having a display area. The method further includes initiating, by the panel in the modular display system, a configuration of the panel in response to the attaching. In this embodiment, the configuration of the panel includes panel orientation, panel resolution, panel vertical and horizontal pixel information, or panel spatial configuration in the modular display system. The method also includes displaying, by the panel, a corresponding segment of an image, video, or text, where the corresponding segment is in accordance with the configuration of the panel.

Example 2. The method of example 1, further includes receiving, by the panel, the corresponding segment of the image, video, or text.

Example 3. The method of example 1, further includes receiving, by the panel, an image, video, or text that is to be displayed by the modular display system and generating, by the panel, the corresponding segment of the image, video, or text to be displayed by the panel in accordance with the configuration of the panel.

Example 4. The method of example 3, further includes storing the configuration of the panel in a non-transitory memory storage of the panel.

Example 5. The method of example 1, further includes receiving, by the panel, a first sequence of data packets including a plurality of data packets. Each data packet includes a segment of an image, video, or text that is to be displayed by the modular display system. Each segment is generated in accordance with the configuration of each panel in the modular display system. The method further includes determining, by the panel, a corresponding data packet including the segment to be displayed by the panel and forwarding, by the panel, a second sequence of data packets to a next panel in a data distribution path of the modular display system, the second sequence of data packets being equal to the first sequence of data packets without the corresponding data packet determined by the panel.

Example 6. The method of example 1, further includes storing, by the panel, the corresponding segment of the image, video, or text in a buffer memory of the panel.

Example 7. The method of example 1, further includes receiving, by the panel, a control signal, a frame clock, or a latch signal for signaling. The signaling being used to synchronize the displaying by each panel in the modular display system.

Example 8. The method of example 1, further includes receiving, by the panel, a corresponding delay interval in accordance with a delay in time between a first time of receiving the corresponding segment and a second time of displaying the corresponding segment. The method further includes delaying, by the panel, the displaying of the corresponding segment by the corresponding delay interval.

Example 9. The method of example 1, further includes determining, by the panel, the configuration of the panel and transmitting, by the panel, the configuration of the panel to a data receiver box of the modular display system.

Example 10. The method of example 1, further includes determining, by the panel, the configuration of the panel and storing, by the panel, the configuration of the panel in a memory of the panel.

Example 11. The method of example 1, further includes assigning an internet protocol (IP) address to the panel in response to attaching the panel to the modular display system.

Example 12. A panel in a modular display system includes a substrate assembly and a receiver circuit. The substrate assembly includes a printed circuit board (PCB) having a first side and a second side, a plurality of LEDs coupled to the first side of the PCB, and a driver circuit coupled to the second side of the PCB. The driver circuit is configured to drive the plurality of LEDs. The receiver circuit is connected to the substrate assembly and includes a non-transitory memory storage comprising instructions and a processor in communication with the non-transitory memory storage. The processor executes instructions to initiate a configuration of the panel in response to attaching the panel in a modular display system. The configuration of the panel including panel orientation, panel resolution, panel vertical and horizontal pixel information, or panel spatial configuration in the modular display system. The processor also executes instructions to transmit a corresponding segment of an image, video, or text to be displayed using the substrate assembly. The corresponding segment being in accordance with the configuration of the panel.

Example 13. The panel in example 12, further includes a power supply circuit coupled to the receiver circuit and the substrate assembly. The power supply circuit configured to convert an incoming voltage and current to an operating voltage and operating current of the panel.

Example 14. The panel in example 12, further includes a sensor configured to generate and transmit a signal to a data receiver box of the modular display system in response to the attaching of the panel. The sensor being a near field communication (NFC) sensor, a vicinity sensor, a pressure sensor, or an induction loop panel detector.

Example 15. The panel in example 12, further includes a switch configured to generate and transmit a signal to a data receiver box of the modular display system in response to the attaching of the panel. The switch being an automatic mechanical switch or a manual switch.

Example 16. The panel in example 12, where the processor executes instructions to receive the corresponding segment of the image, video, or text.

Example 17. The panel in example 12, where the processor executes instructions to receive an image, video, or text that is to be displayed by the modular display system. The processor also executes instructions to generate the corresponding segment of the image, video, or text to be displayed by the panel in accordance with the configuration of the panel.

Example 18. The panel in example 17, where the processor executes instructions to store the configuration of the panel in the non-transitory memory storage of the panel.

Example 19. The panel in example 12, where the processor executes instructions to receive a first sequence of data packets including a plurality of data packets. Each data packet includes a segment of an image, video, or text that is to be displayed by the modular display system. Each segment is generated in accordance with the configuration of each panel in the modular display system. The processor also executes instructions to determine a corresponding data packet including the segment to be displayed by the panel and forward a second sequence of data packets to a next panel in a data distribution path of the modular display system. The second sequence of data packets is equal to the first sequence of data packets without the corresponding data packet determined by the panel.

Example 20. The panel in example 12, where the processor executes instructions to store the corresponding segment of the image, video, or text in the non-transitory memory storage of the panel.

Example 21. The panel in example 12, where the processor executes instructions to receive a control signal, a frame clock, or a latch signal for signaling. The signaling being used to synchronize the corresponding segment to be displayed by each panel in the modular display system.

Example 22. The panel in example 12, where the processor executes instructions to receive a corresponding delay interval in accordance with a delay in time between a first time of receiving the corresponding segment and a second time of displaying the corresponding segment. The processor also executes instructions to delay the displaying of the corresponding segment by the corresponding delay interval.

Example 23. The panel in example 12, where the processor executes instructions to determine the configuration of the panel and transmit the configuration of the panel to a data receiver box of the modular display system.

Example 24. The panel in example 12, where the processor executes instructions to determine the configuration of the panel and store the configuration of the panel in a memory of the panel.

Example 25. The panel in example 12, where the processor executes instructions to assign an internet protocol (IP) address to the panel in response to attaching the panel to the modular display system.

Example 26. A modular display system includes a plurality of panels and a data receiver box. Each panel includes a printed circuit board (PCB) having a first side and a second side, a plurality of LEDs coupled to the first side of the PCB, and a driver circuit coupled to the second side of the PCB. The driver circuit configured to drive the plurality of LEDs. The data receiver box is configured to connect a first panel to a second panel of the plurality of panels and includes a receiver circuit and a power supply circuit. The receiver circuit is configured to initiate a configuration of the first panel and a configuration of the second panel in response to attaching the first panel or the second panel in the modular display system. The configuration of the first panel and the configuration of the second panel includes panel orientation, panel resolution, panel vertical and horizontal pixel information, or panel spatial configuration in the modular display system. The receiver circuit is also configured to transmit a first segment of an image, video, or text to the first panel to be displayed. The first segment being in accordance with the configuration of the first panel. The receiver circuit is further configured to transmit a second segment of an image, video, or text to the second panel to be displayed. The second segment being in accordance with the configuration of the second panel. The power supply circuit is configured to convert an alternating current (AC) signal to a direct current (DC) signal. The DC signal is used to operate each of the plurality of panels and the receiver circuit.

Example 27. The modular display system of example 26, where each panel further includes a sensor configured to generate and transmit a signal to the receiver circuit in response to the attaching of the panel, the sensor being a near field communication (NFC) sensor, a vicinity sensor, a pressure sensor, or an induction loop panel detector.

Example 28. The modular display system of example 26, where each panel further includes a switch configured to generate and transmit a signal to the receiver circuit in response to the attaching of the panel. The switch being an automatic mechanical switch or a manual switch.

Example 29. The modular display system of example 26, where the receiver circuit is further configured to receive the first segment and the second segment from an external source.

Example 30. The modular display system of example 26, where the receiver circuit is further configured to receive an image, video, or text and generate the first segment and the second segment from the image, video, or text. The generating of the first segment is in accordance with the configuration of the first panel and the generating of the second segment is in accordance with the configuration of the second panel.

Example 31. The modular display system of example 26, where the receiver circuit includes a non-transitory memory storage. The receiver circuit is further configured to store the configuration of the first panel and the configuration of the second panel in the non-transitory memory storage of the receiver circuit.

Example 32. The modular display system of example 26, where the receiver circuit is further configured to receive a first sequence of data packets including a plurality of data packets. The plurality of data packets including at least the first segment and the second segment. The receiver circuit is also configured to determine a corresponding data packet including the first segment and the second segment and configured to forward a second sequence of data packets to a next receiver circuit in a data distribution path of the modular display system. The second sequence of data packets is equal to the first sequence of data packets without the first segment and without the second segment.

Example 33. The modular display system of example 26, where the receiver circuit includes a non-transitory memory storage. The receiver circuit is further configured to store the first segment and the second segment in the non-transitory memory storage of the receiver circuit.

Example 34. The modular display system of example 26, where the receiver circuit is further configured to receive a control signal, a frame clock, or a latch signal for signaling. The signaling used to synchronize displaying of a corresponding segment at each panel in the plurality of panels.

Example 35. The modular display system of example 26, where the receiver circuit is further configured to determine the configuration of the first panel and the configuration of the second panel and transmit the configuration of the first panel and the configuration of the second panel to an external source.

Example 36. The modular display system of example 26, where the receiver circuit is further configured to assign an internet protocol (IP) address to the receiver circuit.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. Accordingly, embodiments of the invention include combinations of embodiments described in FIGS. 1-12. As an example, the embodiments described in FIGS. 2A-2B and 4A-4C may be combined with each other in alternative embodiments. It is therefore intended that the appended claims encompass any such modifications or embodiments.

What is claimed is:

1. A method of configuring a modular display system, the method comprising:
attaching a panel to form the modular display system having a display area;
initiating, by the panel in the modular display system, a configuration of the panel in response to the attaching, the configuration of the panel comprising panel orientation, panel resolution, panel vertical and horizontal pixel information, or panel spatial configuration in the modular display system; and
displaying, by the panel, a corresponding segment of an image, video, or text, the corresponding segment being in accordance with the configuration of the panel.

2. The method of claim 1, further comprising receiving, by the panel, the corresponding segment of the image, video, or text.

3. The method of claim 1, further comprising:
receiving, by the panel, an image, video, or text that is to be displayed by the modular display system; and
generating, by the panel, the corresponding segment of the image, video, or text to be displayed by the panel in accordance with the configuration of the panel.

4. The method of claim 3, further comprising storing the configuration of the panel in a non-transitory memory storage of the panel.

5. The method of claim 1, further comprising:
receiving, by the panel, a first sequence of data packets comprising a plurality of data packets, each data packet comprising a segment of an image, video, or text that is to be displayed by the modular display system, each segment generated in accordance with the configuration of each panel in the modular display system;
determining, by the panel, a corresponding data packet comprising the segment to be displayed by the panel; and
forwarding, by the panel, a second sequence of data packets to a next panel in a data distribution path of the modular display system, the second sequence of data packets being equal to the first sequence of data packets without the corresponding data packet determined by the panel.

6. The method of claim 1, further comprising storing, by the panel, the corresponding segment of the image, video, or text in a buffer memory of the panel.

7. The method of claim 1, further comprising receiving, by the panel, a control signal, a frame clock, or a latch signal for signaling, the signaling used to synchronize the displaying by each panel in the modular display system.

8. The method of claim 1, further comprising:
receiving, by the panel, a corresponding delay interval in accordance with a delay in time between a first time of receiving the corresponding segment and a second time of displaying the corresponding segment; and
delaying, by the panel, the displaying of the corresponding segment by the corresponding delay interval.

9. The method of claim 1, further comprising:
determining, by the panel, the configuration of the panel; and
transmitting, by the panel, the configuration of the panel to a data receiver box of the modular display system.

10. The method of claim 1, further comprising:
determining, by the panel, the configuration of the panel; and
storing, by the panel, the configuration of the panel in a memory of the panel.

11. The method of claim 1, further comprising assigning an internet protocol (IP) address to the panel in response to attaching the panel to the modular display system.

12. A panel in a modular display system, the panel comprising:
a substrate assembly comprising:
a printed circuit board (PCB) having a first side and a second side;
a plurality of LEDs coupled to the first side of the PCB;
a driver circuit coupled to the second side of the PCB, the driver circuit configured to drive the plurality of LEDs;
a receiver circuit coupled to the substrate assembly, the receiver circuit comprising:
a non-transitory memory storage comprising instructions;
a processor in communication with the non-transitory memory storage, the processor executes instructions to:
initiate a configuration of the panel in response to attaching the panel in a modular display system, the configuration of the panel comprising panel orientation, panel resolution, panel vertical and horizontal pixel information, or panel spatial configuration in the modular display system; and
transmit a corresponding segment of an image, video, or text to be displayed using the substrate assembly, the corresponding segment being in accordance with the configuration of the panel.

13. The panel in claim 12, further comprising:
a power supply circuit coupled to the receiver circuit and the substrate assembly, the power supply circuit configured to convert an incoming voltage and current to an operating voltage and operating current of the panel.

14. The panel in claim 12, further comprising:
a sensor configured to generate and transmit a signal to a data receiver box of the modular display system in response to the attaching of the panel, the sensor being a near field communication (NFC) sensor, a vicinity sensor, a pressure sensor, or an induction loop panel detector.

15. The panel in claim 12, further comprising:
a switch configured to generate and transmit a signal to a data receiver box of the modular display system in response to the attaching of the panel, the switch being an automatic mechanical switch or a manual switch.

16. The panel in claim 12, wherein the processor executes instructions to receive the corresponding segment of the image, video, or text.

17. The panel in claim 12, wherein the processor executes instructions to:
receive an image, video, or text that is to be displayed by the modular display system; and
generate the corresponding segment of the image, video, or text to be displayed by the panel in accordance with the configuration of the panel.

18. The panel in claim 17, wherein the processor executes instructions to store the configuration of the panel in the non-transitory memory storage of the panel.

19. The panel in claim 12, wherein the processor executes instructions to:
receive a first sequence of data packets comprising a plurality of data packets, each data packet comprising a segment of an image, video, or text that is to be displayed by the modular display system, each segment generated in accordance with the configuration of each panel in the modular display system;
determine a corresponding data packet comprising the segment to be displayed by the panel; and
forward a second sequence of data packets to a next panel in a data distribution path of the modular display system, the second sequence of data packets being equal to the first sequence of data packets without the corresponding data packet determined by the panel.

20. The panel in claim 12, wherein the processor executes instructions to store the corresponding segment of the image, video, or text in the non-transitory memory storage of the panel.

21. The panel in claim 12, wherein the processor executes instructions to receive a control signal, a frame clock, or a latch signal for signaling, the signaling used to synchronize the corresponding segment to be displayed by each panel in the modular display system.

22. The panel in claim 12, wherein the processor executes instructions to:
receive a corresponding delay interval in accordance with a delay in time between a first time of receiving the corresponding segment and a second time of displaying the corresponding segment; and
delay the displaying of the corresponding segment by the corresponding delay interval.

23. The panel in claim 12, wherein the processor executes instructions to:
determine the configuration of the panel; and
transmit the configuration of the panel to a data receiver box of the modular display system.

24. The panel in claim 12, wherein the processor executes instructions to:
determine the configuration of the panel; and
store the configuration of the panel in a memory of the panel.

25. The panel in claim 12, wherein the processor executes instructions to assign an internet protocol (IP) address to the panel in response to attaching the panel to the modular display system.

26. A modular display system comprising:
a plurality of panels, each panel comprising:
a printed circuit board (PCB) having a first side and a second side;
a plurality of LEDs coupled to the first side of the PCB;
a driver circuit coupled to the second side of the PCB, the driver circuit configured to drive the plurality of LEDs;
a data receiver box configured to couple a first panel to a second panel of the plurality of panels, the data receiver box comprising:
a receiver circuit configured to:
initiate a configuration of the first panel and a configuration of the second panel in response to attaching the first panel or the second panel in the modular display system, the configuration of the first panel and the configuration of the second panel comprising panel orientation, panel resolution, panel vertical and horizontal pixel information, or panel spatial configuration in the modular display system; and
transmit a first segment of an image, video, or text to the first panel to be displayed, the first segment being in accordance with the configuration of the first panel;
transmit a second segment of an image, video, or text to the second panel to be displayed, the second segment being in accordance with the configuration of the second panel; and
a power supply circuit configured to convert an alternating current (AC) signal to a direct current (DC) signal, the DC signal used to operate each of the plurality of panels and the receiver circuit.

27. The modular display system of claim 26, wherein each panel further comprises:
a sensor configured to generate and transmit a signal to the receiver circuit in response to the attaching of the panel, the sensor being a near field communication (NFC) sensor, a vicinity sensor, a pressure sensor, or an induction loop panel detector.

28. The modular display system of claim 26, wherein each panel further comprises:
a switch configured to generate and transmit a signal to the receiver circuit in response to the attaching of the panel, the switch being an automatic mechanical switch or a manual switch.

29. The modular display system of claim 26, wherein the receiver circuit is further configured to receive the first segment and the second segment from an external source.

30. The modular display system of claim 26, wherein the receiver circuit is further configured to:
receive an image, video, or text; and
generate the first segment and the second segment from the image, video, or text, the generating of the first segment being in accordance with the configuration of the first panel, and the generating of the second segment being in accordance with the configuration of the second panel.

31. The modular display system of claim 26, wherein the receiver circuit comprises a non-transitory memory storage, and the receiver circuit is further configured to store the configuration of the first panel and the configuration of the second panel in the non-transitory memory storage of the receiver circuit.

32. The modular display system of claim 26, wherein the receiver circuit is further configured to:
receive a first sequence of data packets comprising a plurality of data packets, the plurality of data packets comprising at least the first segment and the second segment;
determine a corresponding data packet comprising the first segment and the second segment; and
forward a second sequence of data packets to a next receiver circuit in a data distribution path of the modular display system, the second sequence of data packets being equal to the first sequence of data packets without the first segment and without the second segment.

33. The modular display system of claim 26, wherein the receiver circuit comprises a non-transitory memory storage, and the receiver circuit is further configured to store the first segment and the second segment in the non-transitory memory storage of the receiver circuit.

34. The modular display system of claim 26, wherein the receiver circuit is further configured to receive a control signal, a frame clock, or a latch signal for signaling, the signaling used to synchronize displaying of a corresponding segment at each panel in the plurality of panels.

35. The modular display system of claim 26, wherein the receiver circuit is further configured to:
determine the configuration of the first panel and the configuration of the second panel; and
transmit the configuration of the first panel and the configuration of the second panel to an external source.

36. The modular display system of claim 26, wherein the receiver circuit is further configured to assign an internet protocol (IP) address to the receiver circuit.
